(19) United States
(12) Patent Application Publication
(10) Pub. No.: US 2023/0238596 A1
(43) Pub. Date: Jul. 27, 2023

(54) BATTERY MANAGEMENT SYSTEM INCLUDING CAPACITANCE MEASUREMENT FOR MONITORING BATTERY CELL HEALTH

(71) Applicant: GM GLOBAL TECHNOLOGY OPERATIONS LLC, Detroit, MI (US)

(72) Inventors: Michael P. BALOGH, Novi, MI (US); Andrew J. Galant, Shelby Township, MI (US); Shaomao Xu, Sterling Heights, MI (US); Erik Damon Huemiller, Waterford, MI (US); Nicholas Paul William Pieczonka, Windsor (CA); Ratandeep Singh Kukreja, Warren, MI (US); Daad Bourhan Haddad, Warren, MI (US); Ryan Curtis Sekol, Grosse Pointe Woods, MI (US)

(21) Appl. No.: 17/586,181

(22) Filed: Jan. 27, 2022

(51) Int. Cl. H01M 10/48; H01M 50/105

(52) U.S. Cl. CPC H01M 10/482; H01M 50/105; H01M 2220/20

(57) ABSTRACT

A battery cell comprises a battery cell enclosure made of a non-metallic material. First battery terminals arranged in the battery cell enclosure. Second battery terminals arranged in the battery cell enclosure. Electrolyte is located between the first battery terminals and the second battery terminals. C conductive portions are arranged adjacent to an outer surface of the battery cell enclosure, where C is an integer greater than zero.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery systems, and more particularly to battery monitoring systems for battery cells of electric vehicles.

Electric vehicles (EVs) such as battery electric vehicles (BEVs), hybrid vehicles, and/or fuel cell vehicles include one or more electric machines and a battery system including one or more battery cells. The battery cells can be arranged in battery modules including two or more battery cells and/or in battery packs including two or more battery modules. A power control system is used to control charging and/or discharging of the battery system during charging from a utility, regenerative braking and/or acceleration during driving.

A battery management system (BMS) monitors various parameters of the battery system and controls the operation of the battery system. The battery cells include solid or liquid electrolyte arranged between an anode and a cathode of the battery cell. Over the lifetime of the battery, performance of the battery may decrease due to an interconnected combination of electrolyte dry out, chemistry changes of the solid or liquid electrolyte, loss of active lithium inventory and/or changes in the active materials in the battery cells. It is difficult to detect these conditions with the BMS.

### SUMMARY

A battery cell comprises a battery cell enclosure made of a non-metallic material. First battery terminals arranged in the battery cell enclosure. Second battery terminals arranged in the battery cell enclosure. Electrolyte is located between the first battery terminals and the second battery terminals. C conductive portions are arranged adjacent to an outer surface of the battery cell enclosure, where C is an integer greater than zero.

In other features, C is greater than one. The C conductive portions comprise a metal foil layer. The battery cell comprises a pouch-type battery cell and the battery cell enclosure comprises a battery pouch. The battery cell enclosure includes a plurality of layers and wherein the metal foil layer is laminated between two adjacent layers of the plurality of layers of the battery pouch.

A battery system comprises a battery module enclosure and N-1 additional ones of the battery cell arranged in the battery module enclosure, where N is an integer greater than one. Compression material is arranged between adjacent ones of the N battery cells in the battery module enclosure. A first one of the conductive portions of a first one of the N battery cells is arranged between the compression material and an outer surface of the first one of the N battery cells.

A battery system comprises N-1 additional ones of the battery cell of claim 1, where N is an integer greater than one. A controller includes a capacitance measurement module configured to measure capacitance values between at least one of: the C conductive portions of at least one of the N battery cells and at least one of the first battery terminals and the second battery terminals of the at least one of the N battery cells; and at least two of the C conductive portions.

In other features, the capacitance measurement module is configured to measure an effective dielectric constant of the N battery cells by at least one of charging and discharging the C conductive portions of at least one of the N battery cells with a predetermined current and measuring a rate of rise of a resulting voltage. The capacitance measurement module is configured to measure an effective dielectric constant of the battery cell by passing current having a predetermined frequency through the C conductive portions of at least one of the N battery cells and measuring a resulting voltage and current. The controller is configured to assess the battery state of health at least partially in response to the capacitance values.

In other features, the capacitance measurement module is configured to measure the capacitance values at a plurality of frequencies to assess the battery state of health. The capacitance measurement module is configured to estimate an electrolyte level of the N battery cells based on corresponding ones of the capacitance values. The capacitance measurement module is configured to estimate remaining battery life based on the capacitance values. The capacitance measurement module is configured to at least one of detect and predict battery thermal runaway based on the capacitance values.

A battery system comprises N battery cells, wherein each of the N battery cells comprises a pouch-type battery including a pouch. First battery terminals are arranged in the pouch. Second battery terminals are arranged in the pouch. Electrolyte is located between the first battery terminals and the second battery terminals. C conductive portions are arranged adjacent to one or more outer surfaces of the pouch, where C is an integer greater than zero. A controller includes a capacitance measurement module configured to measure capacitance values between the C conductive portions of the N battery cells and at least one of the first battery terminals and the second battery terminals of the N battery cells.

In other features, C is greater than one and wherein the C conductive portions comprise a metal foil layer. The pouch includes a plurality of layers and wherein the metal foil layer is laminated between at least two of the plurality of layers of the battery pouch.

In other features, compression material arranged between adjacent ones of the N battery cells in a battery module enclosure. At least one of the conductive portions of at least one of the N battery cells is arranged between the compression material and an outer surface of the at least one of the N battery cells.

The controller is configured to at least one of assess the battery state of health at least partially in response to the capacitance values; measure the capacitance values at a plurality of frequencies to assess the battery state of health; estimate an electrolyte level of the N battery cells based on corresponding ones of the capacitance values; and at least one of detect and predict battery thermal runaway based on the capacitance values.

In other features, the controller is configured to adjust at least one operating parameter of the battery system in response to the capacitance values.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of an example of a battery cell with one or more conductive portions attached to one or more surfaces thereof according to the present disclosure;

FIGS. 2A and 2B are electrical schematics of equivalent capacitive circuits;

FIG. 3 is a cross-sectional view of another example of a battery cell including a plurality of conductive portions attached to one or more side surfaces thereof according to the present disclosure;

FIG. 4 is a cross-sectional view of another example of a battery cell including an array of conductive portions attached to one or more side surfaces thereof according to the present disclosure;

FIG. 5 is a cross-sectional view of an example of a battery module including a plurality of battery cells that are separated by compression material according to the present disclosure;

FIG. 6 is a graph illustrating measured capacitance as a function of battery cycles for a battery cell;

FIG. 7 is a functional block diagram of an example of a battery management system with a capacitive measurement module according to the present disclosure; and

FIG. 8 is a flowchart of an example of a method for operating a battery management system including a capacitance measurement module according to the present disclosure.

In the drawings, reference numbers may be reused to identify similar and/or identical elements.

### DETAILED DESCRIPTION

A battery system according to the present disclosure includes one or more battery cells each with one or more conductive portions attached to or integrated into a battery cell enclosure. A capacitance measurement module selectively initiates capacitive measurements on the battery cells using the one or more conductive portions and evaluates the health of the battery cell and/or electrolyte in the battery cell based thereon. The capacitance measurement module is used to measure capacitance values between the conductive portions and internal conducting structures of the battery cells such as terminals of the battery cells.

Changes in the measured capacitance values for each battery cell are monitored over time and are used to detect or predict battery cell aging, electrolyte consumption at the battery cell level, and/or other wear-related operating conditions of the battery cell. The capacitance values may also be used (with or without other battery cell parameters) to detect or predict thermal runaway of the battery cell and/or other battery operating conditions. Because the measured capacitance values are highly dependent upon the dielectric properties of the electrolyte, the battery system can be used to detect small changes in the molecular and physical structures of the battery cells.

Advantages of the battery monitoring system described herein include a simple design that is sensitive to changes in the electrolyte chemistry and/or the operation of the battery cells. The capacitance measurements can be made with high accuracy, speed and repeatability. The additional hardware that is needed on the battery cells takes up minimal space. The capacitance measurements are non-invasive to the battery cells. Overall, the battery management system with the capacitance measurement module provides functional improvements at a relatively low cost.

The capacitance measurement module according to the present disclosure measures one or more the capacitance values of the battery cells using the conductive portions arranged on outer surface(s) of the battery cells. Capacitance measurements are made between the one or more conductive portions and internal conducting structures of the battery cells such as terminals of the battery cells. In some examples, a plurality of conductive portions and/or an array of conductive portions are attached to the outer surface of the battery enclosure to provide spatially resolved capacitance measurements across different areas of the battery cells.

In some examples, the one or more capacitive portions include a flexible metal foil layer. In some examples, the battery cells are arranged in a battery module enclosure with compression material arranged between the battery cells. In some examples, the metal foil layer is arranged between the battery enclosure of the battery cell and the compression material. In some examples, the metal foil layer is laminated between adjacent layers of a battery pouch.

In some examples, the capacitance measurement module is configured to measure an effective dielectric constant K_{eff} of each of the battery cells by charging and/or discharging the conductive portions of the battery cells with a predetermined current and measuring a rate of rise of a resulting voltage. In other examples, a frequency response analyzer measures a magnitude and phase relationship between the input and output voltage and current waveforms at a predetermined frequency or as a function of frequency. In some examples, the current or voltage of the applied waveform is modulated during measurement.

In some examples, the battery management system stores the measured capacitance values for the battery cells as a function of battery cycles and then performs further calculations and/or applies functions or modelling to assess battery state of health (SOH). In some examples, the capacitance measurements are made at multiple frequencies to assess the battery SOH.

In some examples, the battery system utilizes the capacitance measurements to detect or monitor progression of electrolyte dry out and/or to predict when the battery cell will dry out. In some examples, the battery management system incorporates a comparative capacitance measurement made from different locations on one side of a battery cell, or measurements made from two sides or two locations of the battery cell. In some examples, the battery management system uses the capacitance measurements to forecast chemical degradation of materials of the battery cell. In some examples, the battery management system uses the capacitance measurements to detect or predict battery thermal runaway.

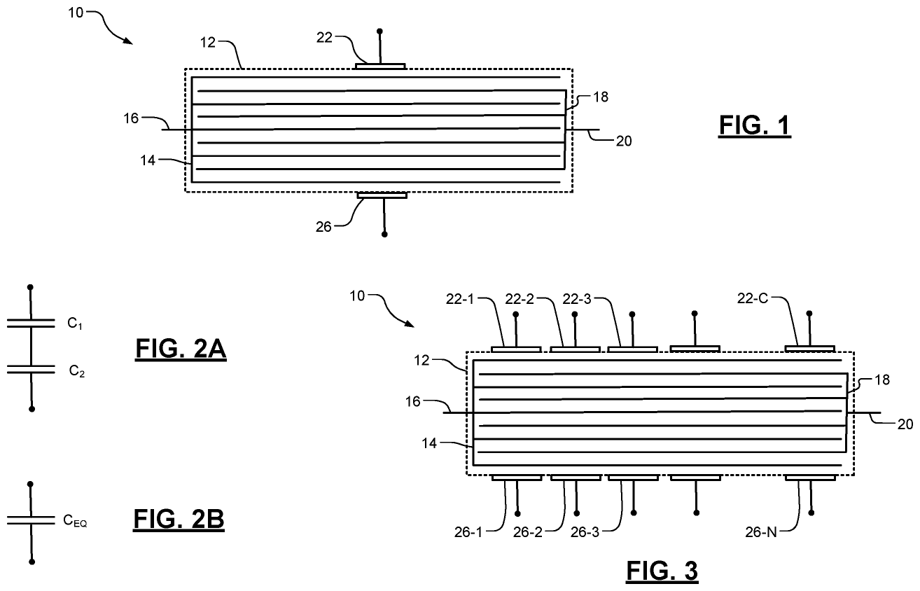

Referring now to FIG. 1, a battery cell 10 includes one or more conductive portions 22 and/or 26 that are used by a capacitance measurement module (not shown in FIG. 1) to measure capacitance of the battery cell 10. The battery cell 10 includes a battery cell enclosure 12. In some examples, the battery cell 10 comprises a pouch-type battery cell and the battery cell enclosure 12 comprises a pouch, although other types of battery cells and/or battery cell enclosures can be used. In some examples, the battery cell enclosure 12 is made of a non-metallic material. In some examples, the battery cell enclosure 12 is made of a non-metallic, insulative, flexible material.

The battery cell 10 further includes first terminals 14 connected to a first tab 16 and second terminals 18 connected to a second tab 20. The first terminals 14 are attached to cathodes or anodes of the battery cell 10 and the second terminals 18 are attached to the anodes or cathodes of the battery cell 10.

The capacitance measurement module described further below is connected to a first conductive portion 22 arranged on one outer surface of the battery cell enclosure 12. The capacitance measurement module is further connected to a second conductive portion 26 (if used) arranged on another outer surface of the battery cell enclosure 12. In some examples, the first conductive portion 22 and the second conductive portion 26 comprise a flexible metallic foil layer or a thin metal plate, although other types of conductive portions can be used.

In use, the capacitance measurement module measures capacitance between the first conductive portion 22 and one or both of the terminals (e.g. 14 or 18), between the second conductive portion 26 and one or both of the terminals (e.g. 14 or 18), and/or between the first conductive portion 22 and the second conductive portion 26. As can be appreciated, the battery cell 12 may include solid electrolyte or liquid electrolyte.

When measuring capacitance between two conductive plates (e.g. such as the conductive portion 22 and the terminals 14), the capacitance C is equal to ε₀*K_{eff}*A/d (where A is the area of the conducting plates, K_{eff} is the effective dielectric constant, d is the distance between the conducting plates, and ε₀ is the vacuum permittivity). Since the values of ε₀, A and d remain relatively constant over time, the change in the measured capacitance values predominantly reflects changes in the electrolyte over time.

By periodically measuring the capacitance values of the battery cell over time, changes in the effective dielectric constant K_{eff} can be tracked. Based on those changes, the health of the battery cell (due to changes in the solid or liquid electrolyte) can be evaluated and the health of the battery cell can be determined.

Furthermore, changes in the health of the battery cell can be used to adjust operation of the electric vehicle. Examples of operational changes include changes to charging or discharging thresholds, changes to cell balancing parameters, etc. In some examples, the capacitance measurements and/or related battery health data are sent to a remote server for further analysis. The remote server updates calibration data and sends the calibration data back to the electric vehicle via the telematics system. The updated calibration data can be used by a propulsion controller, the battery management system or other vehicle control system to change operation of the electric vehicle.

Referring now to FIGS. 2A and 2B, electrical schematics of equivalent capacitive circuits are shown. In the case where two conductive portions are used on opposite surfaces of a battery cell as shown in FIG. 1, the resulting capacitance value may comprise two capacitors connected in series. When two capacitors C1 and C2 are connected in series, the equivalent capacitance is equal to:

1/Ceq=1/C1+1/C2.

Referring now to FIG. 3, another capacitance measurement module for the battery cell 10 is shown to include a plurality of conductive portions 22-1, 22-2, . . . , and 22-C arranged on one surface of the battery cell enclosure 12 (where C is an integer greater than one). In some examples, the battery cell 10 further includes a plurality of conductive portions 26-1, 26-2, . . . , and 26-N arranged on another surface of the battery cell enclosure 12. As can be appreciated, multiple capacitance measurements can be made using the plurality of conductive portions 22-1, 22-2, . . . , and 22-C and/or the plurality of conductive portions 26-1, 26-2, . . . , and 26-N (where N is an integer greater than one).

Referring now to FIG. 4, another capacitance measurement module for the battery cell 10 is shown to include an X by Y array of conductive portions 22-11, 22-12, . . . , 22-1Y, . . . and 22-XY arranged on one surface of the battery cell enclosure 12 (where X and Y are integers greater than one). In some examples, the battery cell 10 also includes another array of conductive portions located on another surface thereof (not shown). As can be appreciated, multiple types of capacitance measurements may be made using the array of conductive portions 22-11, 22-12, . . . , and 22-XY.

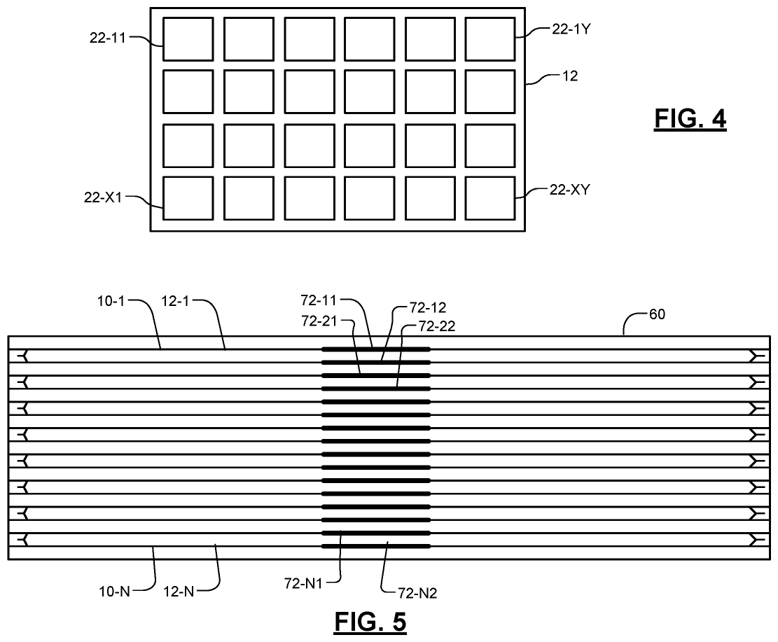

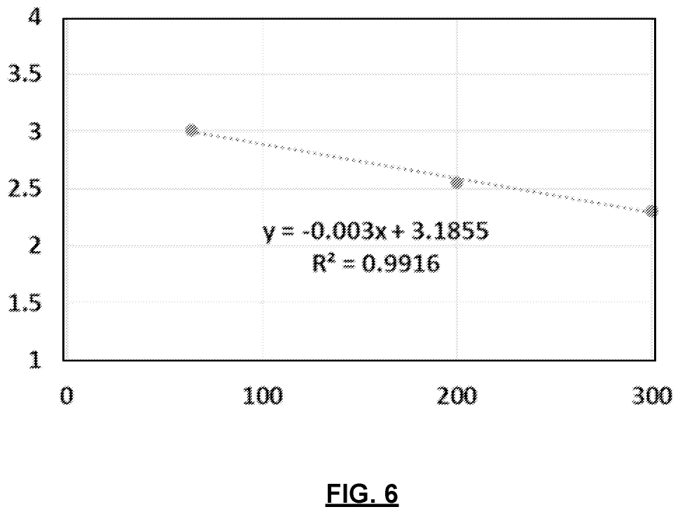

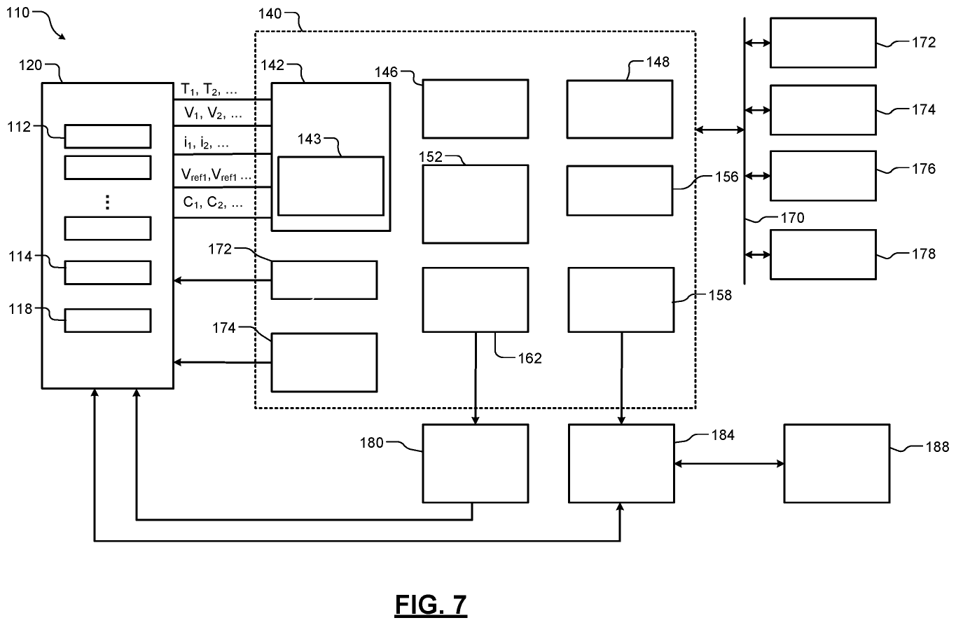

Referring now to FIG. 5, a battery module enclosure 60 houses a plurality of battery cells 10-1, 10-2, . . . and 10-N. Compression material 62 is arranged between adjacent ones of plurality of battery cells 10-1, 10-2, . . . , and 10-N when installed in the battery module enclosure 60. The compression material 62 maintains side compressive force on the battery cell enclosures 12-1, 12-2, . . . , and 12-N. In some examples, the battery module enclosure 60 comprises a rigid structure to provide lateral support to compress the battery cells and the compression material.

Conductive portions 72-11 and 72-12, 72-21 and 72-22, . . . , 72-N1 and 72-N2 are arranged on opposite side surfaces of the plurality of battery cells 10-1, 10-2, . . . and 10-N. The conductive portions 72-11 and 72-12, 72-21 and 72-22, . . . , 72-N1 and 72-N2 are sandwiched between the compression material 62 and the corresponding outer surfaces of the battery cells 10-1, 10-2, . . . and 10-N. While one conductive portion is shown on each side, other combinations of conductive portions can be used.

Referring now to FIG. 6, a graph of capacitance values as a function of battery cycles is shown for a typical battery cell. As the number of battery cycles increases, the capacitance value and the effective dielectric constant K_{eff} decrease. In some examples, the capacitance value and the effective dielectric constant K_{eff} decrease linearly or non-linearly with the number of cycles. In some examples, the capacitance values are stored as a function of the number of cycles (or other parameters) and are used to define one or more relationships such as linear or non-linear relationships. Modelling can be performed based on the capacitance values and/or other battery cell parameters such as SOH, temperature, SOC and/or other battery cell values. The linear or non-linear relationships, functions and/or models are used to predict when the electrolyte level will fall below a predetermined level, thermal runaway, and/or other operating conditions.

The capacitance measurements can be recorded as a function of time and/or a number of battery cycles (or based on other period and/or events). Based on the capacitance measurements, the capacitance measurement module identifies trends using line fitting such as least means squares (LMS) and/or other types of modelling. As a result of these calculations, the estimated lifetime of the battery cell can be determined.

For example, the estimated lifetime of the battery may correspond to the measured capacitance of the battery cell falling below a predetermined capacitance value. Based on the line fitting, LMS or modelling, the capacitance measurement module estimates the number of battery cycles when the measured capacitance value will reach the predetermined capacitance value. The capacitance measurement module may provide an estimated future date corresponding to the end of life of the battery cell based on the average number of battery cycles used per day or another period and project the number of days until the end of life.

Furthermore, based on changes to the state of health (SOC), state of charge (SOC), and/or the capacitance values, changes to the operation of the battery system can be made. Examples of changes include altering charging or regeneration levels, discharging levels and/or cell balancing parameters. The changes can be determined locally by one of the vehicle controllers. In other examples, the capacitance values and/or other battery parameters are transmitted remotely via a telematics system for remote analysis by a remote server. After the remote analysis, the server updates to the battery parameters and/or thresholds and sends them to the telematics system of the electric vehicle.

Referring now to FIG. 7, an example of a battery system 110 is shown. The battery system 110 includes a battery module 120 including a plurality of battery cells 112, one or more sensors 114 (such as voltage, current, temperature, etc), and a module controller 116. The module controller 116 may be used to control module level sensing and/or functionality.

A battery management system 140 includes a measurement module 142 that coordinates measurement of values from the battery cell, module and/or pack level. Examples of values include temperatures T₁, T₂, . . . , voltages V₁, V₂, . . . , currents C₂, . . . , reference voltages V_{ref1}, V_{ref2}, . . . , etc. The measurement module 142 includes a capacitance measurement module 143 that measure one or more capacitance values C₁, C₂, . . . for each of the battery cells and/or performs other calculations described herein.

A state of health (SOH) module 146 calculates the SOH of the battery cells, modules, and/or packs. A scheduling and history module 148 schedules testing of the battery cells at predetermined periods (e.g. operating time, cycles, etc), in response to predetermined events and/or in response to other factors and stores historical data. A state of change (SOC)/capacity estimation module 152 determines the SOC of the battery cells, modules and/or packs. Calibration data storage 156 stores thresholds, parameters and/or other data related to calibration of the battery system. A thermal management module 162 communicates with a temperature controller 180 to control a temperature of the battery system such as by adjusting coolant flow, airflow and/or other parameters. A power control module 158 controls a power inverter 184 connecting the battery system to one or more loads 188. The battery management system 140 communicates via a vehicle data bus 170 with a propulsion controller 172, one or more other vehicle controllers 174 and/or a telematics controller 178.

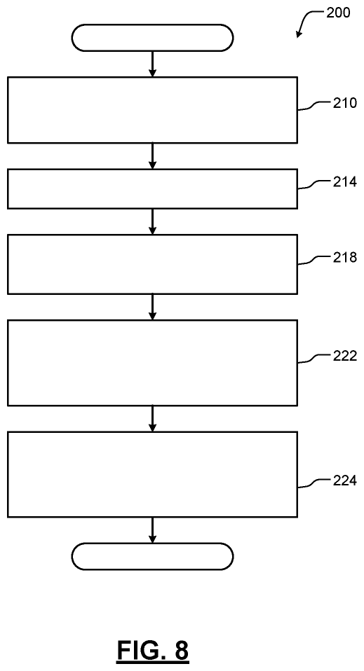

Referring now to FIG. 8, a method 200 for operating a battery management system including a capacitance measurement module according to the present disclosure is shown. At 210, one or more capacitance values of the battery cells are measured at one or more locations. At 214, the capacitance values are stored. At 218, one or more other parameters are calculated based on stored capacitance values (and the calculated parameters are stored). At 222, stored values and the calculated parameters are compared to predetermined thresholds, rates of change or other values. In other examples, the stored values and calculated parameters (along with other data) are used to train a model and/or to access a lookup table.

At 224, one or more operating parameters of the battery system are adjusted based on the comparison. Examples of the operating parameters include cell balancing, charging levels and/or rate, discharging levels and/or rate, and/or other operating parameters.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A battery cell comprising:
a battery cell enclosure made of a non-metallic material;
first battery terminals arranged in the battery cell enclosure;
second battery terminals arranged in the battery cell enclosure;
electrolyte located between the first battery terminals and the second battery terminals; and
C conductive portions arranged adjacent to an outer surface of the battery cell enclosure, where C is an integer greater than zero.

2. The battery cell of claim 1, wherein C is greater than one.

3. The battery cell of claim 1, wherein the C conductive portions comprise a metal foil layer.

4. The battery cell of claim 3, wherein the battery cell comprises a pouch-type battery cell and the battery cell enclosure comprises a battery pouch.

5. The battery cell of claim 3, wherein the battery cell enclosure includes a plurality of layers and wherein the metal foil layer is laminated between two adjacent layers of the plurality of layers of the battery pouch.

6. A battery system comprising:
a battery module enclosure;
N-1 additional ones of the battery cell of claim 1 arranged in the battery module enclosure, where N is an integer greater than one; and
compression material arranged between adjacent ones of the N battery cells in the battery module enclosure,
wherein a first one of the conductive portions of a first one of the N battery cells is arranged between the compression material and an outer surface of the first one of the N battery cells.

7. A battery system comprising:
N-1 additional ones of the battery cell of claim 1, where N is an integer greater than one; and
a controller including a capacitance measurement module configured to measure capacitance values between at least one of:
the C conductive portions of at least one of the N battery cells and at least one of the first battery terminals and the second battery terminals of the at least one of the N battery cells; and
at least two of the C conductive portions.

8. The battery system of claim 7, wherein where the capacitance measurement module is configured to measure an effective dielectric constant of the N battery cells by at least one of charging and discharging the C conductive portions of at least one of the N battery cells with a predetermined current and measuring a rate of rise of a resulting voltage.

9. The battery system of claim 7, wherein where the capacitance measurement module is configured to measure an effective dielectric constant of the battery cell by passing current having a predetermined frequency through the C conductive portions of at least one of the N battery cells and measuring a resulting voltage and current.

10. The battery system of claim 7, wherein the controller is configured to assess the battery state of health at least partially in response to the capacitance values.

11. The battery system of claim 7, wherein the capacitance measurement module is configured to measure the capacitance values at a plurality of frequencies to assess the battery state of health.

12. The battery system of claim 7, wherein the capacitance measurement module is configured to estimate an electrolyte level of the N battery cells based on corresponding ones of the capacitance values.

13. The battery system of claim 7, wherein the capacitance measurement module is configured to estimate remaining battery life based on the capacitance values.

14. The battery system of claim 7, wherein the capacitance measurement module is configured to at least one of detect and predict battery thermal runaway based on the capacitance values.

15. A battery system comprising:
N battery cells,
wherein each of the N battery cells comprises:
a pouch-type battery including a pouch;
first battery terminals arranged in the pouch;
second battery terminals arranged in the pouch;
electrolyte located between the first battery terminals and the second battery terminals; and
C conductive portions arranged adjacent to one or more outer surfaces of the pouch, where C is an integer greater than zero; and
a controller including a capacitance measurement module configured to measure capacitance values between the C conductive portions of the N battery cells and at least one of the first battery terminals and the second battery terminals of the N battery cells.

16. The battery system of claim 15, wherein C is greater than one and wherein the C conductive portions comprise a metal foil layer.

17. The battery system of claim 16, wherein the pouch includes a plurality of layers and wherein the metal foil layer is laminated between at least two of the plurality of layers of the battery pouch.

18. The battery system of claim 15, further comprising:
a battery module enclosure; and
compression material arranged between adjacent ones of the N battery cells in the battery module enclosure,
wherein at least one of the conductive portions of at least one of the N battery cells is arranged between the compression material and an outer surface of the at least one of the N battery cells.

19. The battery system of claim 15, wherein the controller is configured to at least one of:
assess the battery state of health at least partially in response to the capacitance values;
measure the capacitance values at a plurality of frequencies to assess the battery state of health;
estimate an electrolyte level of the N battery cells based on corresponding ones of the capacitance values; and
at least one of detect and predict battery thermal runaway based on the capacitance values.

20. The battery system of claim 15, wherein the controller is configured to adjust at least one operating parameter of the battery system in response to the capacitance values.
